(19) United States
(12) Patent Application Publication
(10) Pub. No.: US 2025/0294780 A1
(43) Pub. Date: Sep. 18, 2025

(54) MAGNETIC MEMORY DEVICE

(71) Applicant: Kioxia Corporation, Tokyo (JP)

(72) Inventors: Masaru TOKO, Kawasaki Kanagawa (JP); Young Min EEH, Yokohama Kanagawa (JP); Taiga ISODA, Yokohama Kanagawa (JP); Hideyuki SUGIYAMA, Kawasaki Kanagawa (JP); Masahiko NAKAYAMA, Yokohama Kanagawa (JP)

(21) Appl. No.: 19/022,760

(22) Filed: Jan. 15, 2025

(30) Foreign Application Priority Data
Mar. 18, 2024 (JP) 2024-041923

(51) Int. Cl. H10B 61/00; H10N 50/10; H10N 50/85

(52) U.S. Cl. CPC H10B 61/20; H10N 50/10; H10N 50/85

(57) ABSTRACT

A magnetic memory device comprises a first magnetic layer having a fixed magnetization direction; a predetermined element containing layer containing at least one predetermined element selected from bismuth (Bi), antimony (Sb), and tellurium (Te); a second magnetic layer provided between the first magnetic layer and the predetermined element containing layer, wherein the second magnetic layer has a variable magnetization direction; and a first non-magnetic layer provided between the first magnetic layer and the second magnetic layer. The second magnetic layer includes a first layer portion having a (100) crystal orientation, and a second layer portion provided between the predetermined element containing layer and the first layer portion, wherein the second layer portion has a (110) crystal orientation.

### CROSS-REFERENCE TO RELATED APPLICATION

This application is based upon and claims the benefit of priority from Japanese Patent Application No. 2024-041923, filed Mar. 18, 2024, the entire contents of which are incorporated herein by reference.

### FIELD

Embodiments described herein relate generally to a magnetic memory device.

### BACKGROUND

A magnetic memory device configured such that a plurality of magnetoresistive effect elements is integrated on a semiconductor substrate has been proposed.

### BRIEF DESCRIPTION OF THE DRAWINGS

FIG. 1 is a schematic cross-sectional view illustrating a basic configuration of a magnetic memory device according to a first embodiment.

FIG. 2 is a schematic cross-sectional view illustrating a basic configuration of a modification of the magnetic memory device according to the first embodiment.

FIG. 3 is a schematic cross-sectional view illustrating a basic configuration of a magnetic memory device according to a second embodiment.

FIG. 4 is a schematic cross-sectional view illustrating a basic configuration of a first modification of the magnetic memory device according to the second embodiment.

FIG. 5 is a schematic cross-sectional view illustrating a basic configuration of a second modification of the magnetic memory device according to the second embodiment.

FIG. 6 is a schematic cross-sectional view illustrating a basic configuration of a third modification of the magnetic memory device according to the second embodiment.

### DETAILED DESCRIPTION

Embodiments provide a magnetic memory device including a magnetoresistive effect element having advantageous properties.

According to embodiments, a magnetic memory device includes a first magnetic layer having a fixed magnetization direction; a predetermined element containing layer containing at least one predetermined element selected from bismuth (Bi), antimony (Sb), and tellurium (Te); a second magnetic layer provided between the first magnetic layer and the predetermined element containing layer, wherein the second magnetic layer has a variable magnetization direction; and a first non-magnetic layer provided between the first magnetic layer and the second magnetic layer. The second magnetic layer includes a first layer portion having a (100) crystal orientation, and a second layer portion provided between the predetermined element containing layer and the first layer portion, wherein the second layer portion has a (110) crystal orientation. Hereinafter, embodiments will be described with reference to the drawings.

### First Embodiment

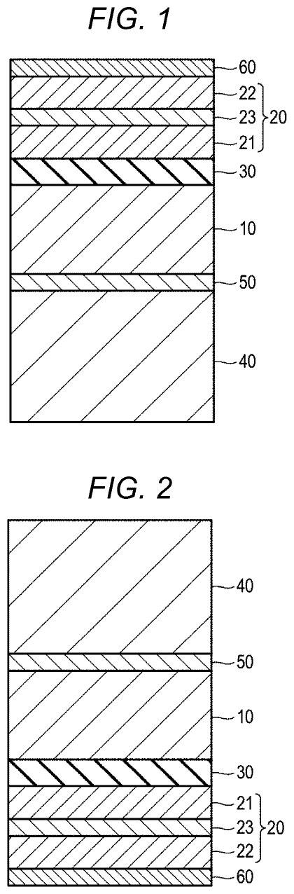

FIG. 1 is a schematic cross-sectional view illustrating a basic configuration of a magnetic memory device according to a first embodiment.

The structure illustrated in FIG. 1 is provided on a lower structure (not illustrated) including a semiconductor substrate, and functions as a magnetoresistive effect element. Specifically, the magnetoresistive effect element functions as a magnetic tunnel junction (MTJ) element exhibiting perpendicular magnetization.

The magnetic memory device of the first embodiment illustrated in FIG. 1 includes a reference layer 10, which is a magnetic layer, a storage layer 20, which is a magnetic layer, a tunnel barrier layer 30, which is a non-magnetic layer, a shift canceling layer 40, which is a magnetic layer, an intermediate layer 50, which is a non-magnetic layer, and a predetermined element containing layer 60. The magnetic memory device has a multilayer structure in which these layers 10 to 60 are stacked on each other.

More specifically, the reference layer 10, the storage layer 20, the tunnel barrier layer 30, and the intermediate layer 50 are provided between the shift canceling layer 40 and the predetermined element containing layer 60. The storage layer 20 is provided between the reference layer 10 and the predetermined element containing layer 60, the tunnel barrier layer 30 is provided between the reference layer 10 and the storage layer 20, and the intermediate layer 50 is provided between the reference layer 10 and the shift canceling layer 40.

The reference layer 10 is a ferromagnetic layer having a fixed magnetization direction, and exhibits perpendicular magnetization. Namely, the magnetization direction of the reference layer 10 is perpendicular to the upper or lower surface of the reference layer 10. The reference layer 10 contains at least one element selected from iron (Fe) and cobalt (Co), and may further contain boron (B). In the first embodiment, the reference layer 10 is formed of a CoFeB layer containing Co, Fe, and B.

The storage layer 20 is a ferromagnetic layer having a variable magnetization direction, and exhibits perpendicular magnetization. Namely, the magnetization direction of the storage layer 20 is perpendicular to the upper or lower surface of the storage layer 20. The storage layer 20 includes a first layer portion 21, a second layer portion 22, and a third layer portion 23.

The first layer portion 21 contacts the tunnel barrier layer 30, and has a (100) crystal orientation that is parallel with the upper or lower surface of the first layer portion 21. As used herein, having a “(100) crystal orientation” means including a crystal structure oriented in the (100) plane. Namely, the lower surface and upper surface of the first layer portion 21 are oriented in the (100) plane. The first layer portion 21 contains at least one element selected from iron (Fe) and cobalt (Co), and may further contain boron (B). In the first embodiment, the first layer portion 21 is preferably formed of a CoFeB layer containing all of Co, Fe, and B.

The second layer portion 22 is provided between the predetermined element containing layer 60 and the first layer portion 21, contacts the predetermined element containing layer 60, and has a (110) crystal orientation. As used herein, having a “(110) crystal orientation” means including a crystal structure oriented in the (110) plane. Namely, the lower surface and upper surface of the second layer portion 22 have a (110) crystal orientation. The second layer portion 22 contains at least one element selected from iron (Fe) and cobalt (Co). In the first embodiment, the second layer portion 22 may be formed of a CoFe layer containing both Co and Fe.

The third layer portion 23 is provided between the first layer portion 21 and the second layer portion 22, and contacts the first layer portion 21 and the second layer portion 22. The third layer portion 23 is provided between the first layer portion 21 and the second layer portion 22 to separate the first layer portion 21 from the second layer portion 22. Separating these layer portions allows for clearly differentiating between the orientation direction of the first layer portion 21, which is the (100)_plane, and the orientation direction of the second layer portion 22, which is the (110) plane. The third layer portion 23 is also provided as such, so that the second layer portion 22 is easily oriented in the (110) plane.

The third layer portion 23 is made of a material containing (1) at least one element selected from ruthenium (Ru), platinum (Pt), iridium (Ir), palladium (Pd), rhodium (Rh), silver (Ag), and gold (Au) or (2) an amorphous magnetic material. As the amorphous magnetic material, e.g., a material (CoZrNb) containing cobalt (Co), zirconium (Zr), and niobium (Nb) or a material (CoZrMo) containing cobalt (Co), zirconium (Zr), and molybdenum (Mo) may be used.

The tunnel barrier layer 30 is an insulating layer, and is formed of a MgO layer containing magnesium (Mg) and oxygen (O). The tunnel barrier layer 30 has a (100) crystal orientation that is parallel with the upper or lower surface of the tunnel barrier layer 30. Namely, the lower surface and upper surface of the tunnel barrier layer 30 are oriented in the same (100) plane as that of the first layer portion 21 of the storage layer 20.

The shift canceling layer 40 is a ferromagnetic layer having a fixed magnetization direction, and exhibits perpendicular magnetization. Namely, the magnetization direction of the shift canceling layer 40 is perpendicular to the upper or lower surface of the shift canceling layer 40. The shift canceling layer 40 has a function of canceling a magnetic field applied from the reference layer 10 to the storage layer 20, and the magnetization direction of the shift canceling layer 40 is antiparallel with the magnetization direction of the reference layer 10. The shift canceling layer 40 has a superlattice crystal structure in which cobalt (Co) and platinum (Pt) are alternately stacked on each other.

The intermediate layer 50 is formed of an iridium (Ir) layer or a ruthenium (Ru) layer, and the reference layer 10 and the shift canceling layer 40 are synthetic antiferromagnetic coupled (SAF coupled) via the intermediate layer 50.

The predetermined element containing layer 60 is provided on the storage layer 20, and functions as a cap layer. The predetermined element containing layer 60 contains at least one predetermined element selected from bismuth (Bi), antimony (Sb), and tellurium (Te). Namely, the predetermined element containing layer 60 may be formed of a Bi layer substantially containing only Bi, an Sb layer substantially containing only Sb, or a Te layer substantially containing only Te. Alternatively, the predetermined element containing layer 60 may be formed of a layer substantially containing two or more elements selected from Bi, Sb, and Te. In addition to the at least one predetermined element selected from Bi, Sb, and Te, the predetermined element containing layer 60 may further contain other elements. In the first embodiment, the predetermined element containing layer 60 is formed of the Bi layer, the Sb layer, and/or the Te layer.

As used herein, “substantially containing” or “substantially formed of” means that a slight amount of an element other than an intended element (e.g., other than one of Bi, Sb, or Te), is allowed to be included in a layer containing the intended element. The same also applies to the description below.

In the first embodiment, the predetermined element containing layer 60 is provided so that a perpendicular magnetic anisotropy of the storage layer 20 is increased and a magnetoresistive effect element having advantageous properties is obtained. The description of such advantageous properties will now be described.

In order to obtain the magnetoresistive effect element having advantageous properties, the perpendicular magnetic anisotropy of the storage layer 20 is increased. However, as the size of the magnetoresistive effect element decreases, it becomes more difficult to obtain the storage layer 20 exhibiting high perpendicular magnetic anisotropy.

In the first embodiment, the predetermined element containing layer 60 formed of the Bi layer, the Sb layer, and/or the Te layer is provided adjacent to the storage layer 20. Bi, Sb, and Te exhibit great spin orbit coupling, and the Bi layer, the Sb layer, and/or the Te layer is provided adjacent to the storage layer 20 so that an interface magnetic anisotropy of the storage layer 20 is increased.

In a case where the Bi layer, the Sb layer, and/or the Te layer is provided adjacent to the storage layer 20, the storage layer 20 is oriented in the (110) plane so that high perpendicular magnetic anisotropy is exhibited. However, in order to obtain advantageous tunnel magnetoresistance (TMR) properties, the storage layer 20 is oriented in the (100) plane at least in the vicinity of an interface between the storage layer 20 and the tunnel barrier layer 30, the tunnel barrier layer 30 being oriented in the (100) plane.

In the first embodiment, the first layer portion 21 of the storage layer 20 has the (100) crystal orientation that is parallel with the upper or lower surface of the first layer portion 21. The second layer portion 22 of the storage layer 20 has the (110) crystal orientation. Thus, in the first embodiment, the first layer portion 21 ensures high TMR, and the second layer portion 22 increases the perpendicular magnetic anisotropy. Namely, the first layer portion 21 adjacent to the tunnel barrier layer 30 ensures high TMR, and the second layer portion 22 exhibiting high perpendicular magnetic anisotropy increases the perpendicular magnetic anisotropy of the entirety of the storage layer 20.

Use of the predetermined element containing layer 60 containing at least one predetermined element selected from Bi, Sb, and Te generally leads to advantages similar to the above-described advantages.

In the first embodiment, the third layer portion 23 is provided between the first layer portion 21 and the second layer portion 22 so that the orientation direction of the first layer portion 21 and the orientation direction of the second layer portion 22 are effectively differentiated from each other. Namely, the first layer portion 21 is oriented in the same (100) plane as that of the tunnel barrier layer 30, and the second layer portion 22 is oriented in the (110) plane with high perpendicular magnetic anisotropy based on the predetermined element containing layer 60.

In order to obtain the above-described structure, a preliminary multilayer structure with layers corresponding to layers 10-60 of the multilayer structure illustrated in FIG. 1, is first formed. In this preliminary multilayer structure, a region corresponding to the first layer portion 21 of the storage layer 20 is in an amorphous state. Namely, in the preliminary multilayer structure, boron is uniformly distributed over the entirety of the region corresponding to the first layer portion 21, and therefore, the region corresponding to the first layer portion 21 is in the amorphous state. Layer structures in the preliminary multilayer structure other than the region corresponding to the first layer portion 21, are similar to those of the multilayer structure illustrated in FIG. 1. In the preliminary structure, the crystal orientation of the second layer portion 22 is differentiated from the crystal orientation of the first layer portion 21 due to the insertion of the third layer portion 23.

As a result of thermal treatment performed on such a preliminary multilayer structure, boron in the region corresponding to the first layer portion 21 is diffused outward, and the region corresponding to the first layer portion 21 changes from the amorphous state to a crystal state. Specifically, the first layer portion 21 becomes oriented in the same (100) plane as that of the tunnel barrier layer 30. As a result, the multilayer structure illustrated in FIG. 1 is obtained.

FIG. 2 is a schematic cross-sectional view illustrating a basic configuration of a modification of the magnetic memory device according to the first embodiment.

The basic structure of the modification is similar to that of the first embodiment. The magnetoresistive effect element of the first embodiment is a top free magnetoresistive effect element configured such that the storage layer 20 is located above the reference layer 10, but the modification is a bottom free magnetoresistive effect element configured such that the storage layer 20 is located below the reference layer 10. Thus, the order of stacking the layers 10 to 60 in the modification is opposite to the order of stacking the layers 10 to 60 in the first embodiment. Moreover, in the modification, the predetermined element containing layer 60 functions as an underlayer.

As described above, the basic structure of the modification is similar to that of the first embodiment, and the modification also obtains advantages similar to those of the first embodiment.

### Second Embodiment

Next, a magnetic memory device according to a second embodiment will be described. Basic matters are similar to those in the first embodiment, and description of such basic matters described in the first embodiment will be omitted.

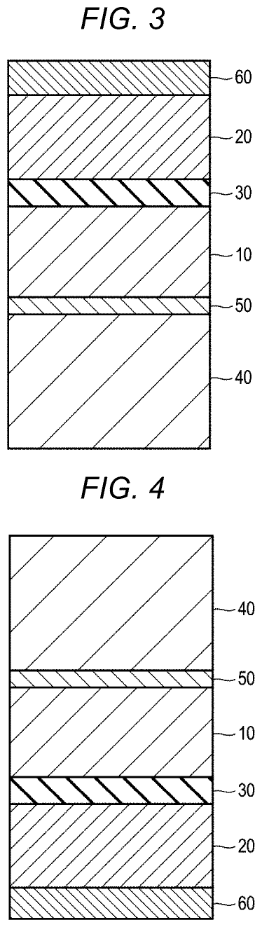

FIG. 3 is a schematic cross-sectional view illustrating a basic configuration of a magnetic memory device according to a second embodiment.

As in the first embodiment, the structure illustrated in FIG. 3 is provided on a lower structure (not illustrated) including a semiconductor substrate, and functions as a magnetoresistive effect element. As in the first embodiment, the magnetoresistive effect element is a MTJ element exhibiting perpendicular magnetization.

As in the first embodiment, the magnetic memory device of the second embodiment illustrated in FIG. 3 includes the reference layer 10, the storage layer 20, the tunnel barrier layer 30, the shift canceling layer 40, the intermediate layer 50, and the predetermined element containing layer 60. The magnetic memory device has a multilayer structure in which these layers 10 to 60 are stacked on each other.

More specifically, the reference layer 10, the storage layer 20, the tunnel barrier layer 30, and the intermediate layer 50 are provided between the shift canceling layer 40 and the predetermined element containing layer 60. The storage layer 20 is provided between the reference layer 10 and the predetermined element containing layer 60, the tunnel barrier layer 30 is provided between the reference layer 10 and the storage layer 20, and the intermediate layer 50 is provided between the reference layer 10 and the shift canceling layer 40.

Basic configurations of the reference layer 10, the tunnel barrier layer 30, the shift canceling layer 40, and the intermediate layer 50 are similar to those of the first embodiment.

The storage layer 20 contacts the tunnel barrier layer 30 and the predetermined element containing layer 60, and includes a layer portion having a (100) crystal orientation that is parallel with the upper or lower surface of the layer portion. Namely, the storage layer 20 includes a layer portion oriented in the (100) plane. This layer portion oriented in the (100) plane contacts the tunnel barrier layer 30. The layer portion oriented in the (100) plane contains at least one element selected from iron (Fe) and cobalt (Co), and may further contain boron (B). In the second embodiment, the layer portion oriented in the (100) plane is preferably formed of a CoFeB layer containing Co, Fe, and B. Moreover, in the second embodiment, the entirety of the storage layer 20 is formed of the layer portion oriented in the (100) plane.

The predetermined element containing layer 60 is provided on the storage layer 20, and functions as a cap layer. The predetermined element containing layer 60 contains (1) at least one first predetermined element selected from bismuth (Bi), antimony (Sb), and tellurium (Te), (2) at least one second predetermined element selected from magnesium (Mg), titanium (Ti), zirconium (Zr), hafnium (Hf), scandium (Sc), yttrium (Y), aluminum (Al), silicon (Si), cerium (Ce), praseodymium (Pr), samarium (Sm), gadolinium (Gd), terbium (Tb), and dysprosium (Dy), and (3) oxygen (O). In addition to the at least one first predetermined element, the at least one second predetermined element, and oxygen, the predetermined element containing layer 60 may further contain other elements.

In the second embodiment, the predetermined element containing layer 60 contains a portion substantially formed of the at least one first predetermined element, the at least one second predetermined element, and oxygen (O). In the second embodiment, the entirety of the predetermined element containing layer 60 is substantially formed of the at least one first predetermined element, the at least one second predetermined element, and oxygen.

Specifically, the predetermined element containing layer 60 may be formed of a compound of the at least one first predetermined element, the at least one second predetermined element, and oxygen. The predetermined element containing layer 60 may have a structure in which the at least one second predetermined element is added to a compound of the at least one first predetermined element and oxygen, or may have a structure in which the at least one first predetermined element is added to a compound of the at least one second predetermined element and oxygen.

As described above, in the second embodiment, the predetermined element containing layer 60 is provided so that a magnetoresistive effect element having advantageous properties is obtained. The description of such advantageous properties will now be described.

As already described, Bi, Sb, and Te used as the first predetermined element exhibit great spin orbit coupling. Thus, the layer 60 containing the first predetermined element is provided adjacent to the storage layer 20 so that the perpendicular magnetic anisotropy of the storage layer 20 is increased.

However, the element (first predetermined element such as Bi, Sb, or Te) exhibiting great spin orbit coupling generally exhibits a great spin pumping effect. Thus, in a comparative example where the predetermined element containing layer 60 is formed of a layer containing only the first predetermined element, a damping value increases, and the inversion current (current necessary for inverting the magnetization direction of the storage layer 20) of the magnetoresistive effect element increases.

The predetermined element containing layer 60 is formed of an oxide layer containing the first predetermined element and oxygen so that the damping value is decreased and the inversion current of the magnetoresistive effect element is decreased. However, without the addition of the second predetermined element, coupling between the first predetermined element and oxygen is weak and thus unstable. When the second predetermined element is added, the resulting coupling between the first and second predetermined elements and oxygen is stable. Particularly, in a comparative example without the addition of the second predetermined element, oxygen contained in the predetermined element containing layer 60 is coupled to boron that diffused to outside the storage layer 20. Accordingly, in the comparative example, much of the oxygen in the predetermined element containing layer 60 has already bonded with boron, and for this reason, it is difficult for coupling between the first predetermined element and oxygen to be stably present in the predetermined element containing layer 60. Thus, the advantage of decreasing the damping value as a result of the coupling between the first predetermined element and oxygen would be reduced.

In the second embodiment, the predetermined element containing layer 60 further contains the second predetermined element in addition to the first predetermined element and oxygen. Coupling between the second predetermined element and oxygen is stronger than coupling between boron and oxygen. Thus, in the second embodiment, coupling between boron and oxygen is reduced. Consequently, in the second embodiment, the first predetermined element and oxygen are stably present in the predetermined element containing layer 60, and the damping value is sufficiently decreased.

As described above, in the second embodiment, the predetermined element containing layer 60 containing the first predetermined element, the second predetermined element, and oxygen, is provided. As a result, that the perpendicular magnetic anisotropy of the storage layer 20 is increased, the damping value is sufficiently decreased by improvement in the stability of the predetermined element containing layer 60, and an increase in the inversion current is effectively minimized. Thus, the magnetoresistive effect element having advantageous properties is obtained.

FIG. 4 is a schematic cross-sectional view illustrating a basic configuration of a first modification of the magnetic memory device according to the second embodiment.

The basic structure of the first modification is similar to that of the second embodiment. The magnetoresistive effect element of the second embodiment is a top free magnetoresistive effect element configured such that the storage layer 20 is located above the reference layer 10. The first modification is a bottom free magnetoresistive effect element configured such that the storage layer 20 is located below the reference layer 10. Thus, the order of stacking the layers 10 to 60 in the first modification is opposite to the order of stacking the layers 10 to 60 in the second embodiment. Moreover, in the first modification, the predetermined element containing layer 60 functions as an underlayer.

As described above, the basic structure of the first modification is similar to that of the second embodiment, and the first modification also obtains advantages similar to those of the second embodiment.

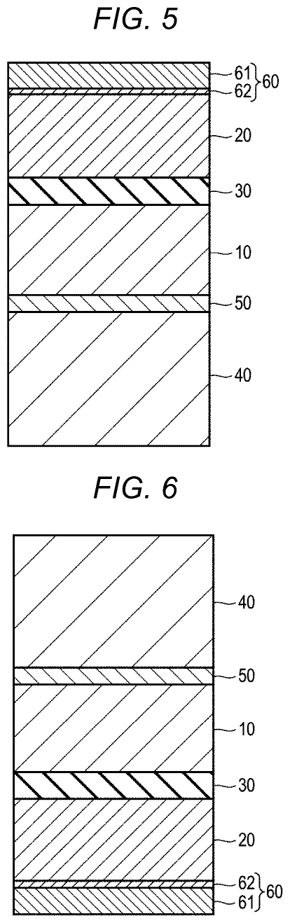

FIG. 5 is a schematic cross-sectional view illustrating a basic configuration of a second modification of the magnetic memory device according to the second embodiment.

The basic structure of the second modification is similar to that of the second embodiment. The predetermined element containing layer 60 contains at least one first predetermined element, at least one second predetermined element, and oxygen (O). As the at least one first predetermined element and the at least one second predetermined element, elements similar to those described above in the second embodiment are used.

In the second modification, the predetermined element containing layer 60 includes a first predetermined element containing layer portion 61 containing the at least one first predetermined element and oxygen (O). The predetermined element containing layer 60 also includes a second predetermined element containing layer portion 62 provided between the storage layer 20 and the first predetermined element containing layer portion 61. The second predetermined element containing layer portion 62 contains the at least one second predetermined element and oxygen (O). Specifically, the predetermined element containing layer 60 includes (1) the first predetermined element containing layer portion 61 substantially formed of the at least one first predetermined element and oxygen (O) and (2) the second predetermined element containing layer portion 62 substantially formed of the at least one second predetermined element and oxygen (O). Namely, the oxide bonded with the first predetermined element is used as the first predetermined element containing layer portion 61, and the oxide bonded with the second predetermined element is used as the second predetermined element containing layer portion 62.

As described above, the basic structure of the second modification is similar to that of the second embodiment, and the second modification also obtains advantages similar to those of the second embodiment.

Specifically, the first predetermined element containing layer portion 61 increases the perpendicular magnetic anisotropy of the storage layer 20 and minimizes an increase in the inversion current. The second predetermined element containing layer portion 62 reduces degradation of the stability of the predetermined element containing layer 60 due to, e.g., diffusion of boron.

In a case where the second predetermined element containing layer portion 62 becomes too thick, the advantage of enhancing the perpendicular magnetic anisotropy of the storage layer 20 by the first predetermined element containing layer portion 61 decreases. For this reason, the thickness of the second predetermined element containing layer portion 62 is preferably less than the thickness of the first predetermined element containing layer portion 61. For example, the thickness of the second predetermined element containing layer portion 62 may be preferably approximately equal to the thickness of a mono-layer of the compound of the second predetermined element and oxygen.

FIG. 6 is a schematic cross-sectional view illustrating a basic configuration of a third modification of the magnetic memory device according to the second embodiment.

The basic structure of the third modification is similar to those of the second embodiment and the second modification. The magnetoresistive effect element of the second modification is a top free magnetoresistive effect element configured such that the storage layer 20 is located above the reference layer 10. The third modification is a bottom free magnetoresistive effect element configured such that the storage layer 20 is located below the reference layer 10. Thus, the order of stacking the layers 10 to 60 in the third modification is opposite to the order of stacking the layers 10 to 60 in the second modification. Moreover, in the third modification, the predetermined element containing layer 60 functions as an underlayer.

As described above, the basic structure of the third modification is similar to those of the second embodiment and the second modification. The third modification also obtains advantages similar to those of the second embodiment and the second modification.

The first and second embodiments have been described above, but the configuration of the first embodiment and the configuration of the second embodiment may be combined. For example, the configuration of the predetermined element containing layer 60 of the second embodiment may be applied to the predetermined element containing layer 60 of the first embodiment. In this case, for example, the predetermined element containing layer 60 is formed with the percentages of the at least one first predetermined element, the at least one second predetermined element, and oxygen (O) adjusted such that the second layer portion 22 oriented in the (110) plane as described in the first embodiment is obtained.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A magnetic memory device comprising:
a first magnetic layer having a fixed magnetization direction;
a predetermined element containing layer containing at least one predetermined element selected from bismuth (Bi), antimony (Sb), and tellurium (Te);
a second magnetic layer provided between the first magnetic layer and the predetermined element containing layer, wherein the second magnetic layer has a variable magnetization direction; and
a first non-magnetic layer provided between the first magnetic layer and the second magnetic layer,
wherein the second magnetic layer includes
a first layer portion having a (100) crystal orientation, and
a second layer portion provided between the predetermined element containing layer and the first layer portion, the second layer portion having a (110) crystal orientation.

2. The magnetic memory device according to claim 1, wherein the second magnetic layer further includes a third layer portion provided between the first layer portion and the second layer portion, the third layer portion being made of a material containing (1) at least one element selected from ruthenium (Ru), platinum (Pt), iridium (Ir), palladium (Pd), rhodium (Rh), silver (Ag), and gold (Au) or (2) an amorphous magnetic material.

3. The magnetic memory device according to claim 2, wherein the amorphous magnetic material is selected from (1) a material containing cobalt (Co), zirconium (Zr), and niobium (Nb) and (2) a material containing cobalt (Co), zirconium (Zr), and molybdenum (Mo).

4. The magnetic memory device according to claim 1, wherein the first layer portion of the second magnetic layer contains at least one element selected from iron (Fe) and cobalt (Co).

5. The magnetic memory device according to claim 4, wherein the first layer portion of the second magnetic layer further contains boron (B).

6. The magnetic memory device according to claim 1, wherein the second layer portion of the second magnetic layer contains at least one element selected from iron (Fe) and cobalt (Co).

7. The magnetic memory device according to claim 1, wherein the first layer portion of the second magnetic layer contacts the first non-magnetic layer.

8. The magnetic memory device according to claim 1, wherein the second layer portion of the second magnetic layer contacts the predetermined element containing layer.

9. The magnetic memory device according to claim 1, wherein the predetermined element containing layer is formed of (1) a bismuth (Bi) layer substantially containing only bismuth (Bi), (2) an antimony (Sb) layer substantially containing only antimony (Sb), or (3) a tellurium (Te) layer substantially containing only tellurium (Te).

10. A magnetic memory device comprising:
a first magnetic layer having a fixed magnetization direction;
a predetermined element containing layer containing (1) at least one first predetermined element selected from bismuth (Bi), antimony (Sb), and tellurium (Te), (2) at least one second predetermined element selected from magnesium (Mg), titanium (Ti), zirconium (Zr), hafnium (Hf), scandium (Sc), yttrium (Y), aluminum (Al), silicon (Si), cerium (Ce), praseodymium (Pr), samarium (Sm), gadolinium (Gd), terbium (Tb), and dysprosium (Dy), and (3) oxygen (O);
a second magnetic layer provided between the first magnetic layer and the predetermined element containing layer, wherein the second magnetic layer has a variable magnetization direction; and
a first non-magnetic layer provided between the first magnetic layer and the second magnetic layer.

11. The magnetic memory device according to claim 10, wherein the second magnetic layer includes a layer portion having a (100) crystal orientation.

12. The magnetic memory device according to claim 11, wherein the layer portion of the second magnetic layer contains at least one element selected from iron (Fe) and cobalt (Co).

13. The magnetic memory device according to claim 12, wherein the layer portion of the second magnetic layer further contains boron (B).

14. The magnetic memory device according to claim 11, wherein the layer portion of the second magnetic layer contacts the first non-magnetic layer.

15. The magnetic memory device according to claim 10, wherein the second magnetic layer contacts the predetermined element containing layer.

16. The magnetic memory device according to claim 10, wherein the predetermined element containing layer contains a portion substantially formed of the at least one first predetermined element, the at least one second predetermined element, and oxygen (O), the portion of the predetermined element containing layer containing an element other than the at least one first predetermined element, the at least one second predetermined element, and oxygen (O).

17. The magnetic memory device according to claim 10, wherein the predetermined element containing layer includes (1) a first predetermined element containing layer portion substantially formed of the at least one first predetermined element and oxygen (O) and (2) a second predetermined element containing layer portion provided between the second magnetic layer and the first predetermined element containing layer portion, the second predetermined element containing layer portion being substantially formed of the at least one second predetermined element and oxygen (O).

18. The magnetic memory device according to claim 17, wherein a thickness of the second predetermined element containing layer portion is less than a thickness of the first predetermined element containing layer portion.

19. The magnetic memory device according to claim 10, wherein the first non-magnetic layer contains magnesium (Mg) and oxygen (O).

20. The magnetic memory device according to claim 10, further comprising:
a third magnetic layer, wherein the first magnetic layer and the third magnetic layer are provided on opposite sides of the first non-magnetic layer; and
a second non-magnetic layer provided between the second magnetic layer and the third magnetic layer.
